(19) United States
(12) Patent Application Publication
(10) Pub. No.: US 2021/0124806 A1
(43) Pub. Date: Apr. 29, 2021

(54) VEHICLE SUSPENSION

(71) Applicant: Ford Global Technologies, LLC, Dearborn, MI (US)

(72) Inventors: Punarjay Chakravarty, Campbell, CA (US); Mohsen Lakehal-ayat, Aachen/NRW (DE); Matthew Blaschko, Kessel-Lo (BE); Sinnu Susan Thomas, Kerala (IN); Jacopo Palandri, Aachen/NRW (DE); Friedrich Peter Wolf-Monheim, Aachen/NRW (DE)

(73) Assignee: Ford Global Technologies, LLC, Dearborn, MI (US)

(21) Appl. No.: 16/662,183

(22) Filed: Oct. 24, 2019

(51) Int. Cl. G06F 17/50; B60G 3/06

(52) U.S. Cl. CPC G06F 17/5009; B60G 2200/142; B60G 3/06

(57) ABSTRACT

A computer, including a processor and a memory, the memory including instructions to be executed by the processor to simulate behavior of a vehicle suspension component based on sampling a geometry space including vehicle suspension component hard-points using Gaussian process modeling and determine one or more vehicle suspension component geometries including vehicle suspension component hard-points based on first kinematic curves corresponding to behavior of the vehicle suspension component.

### BACKGROUND

Wheeled vehicles include front suspension components that permit wheels to move relative to the vehicle's body in response to variations in road surfaces. Front suspension components permit vehicle wheels to roll or be driven by vehicle powertrain components, steered by vehicle steering components, and braked by vehicle braking components in addition to moving relative to the vehicle's body. Vehicle suspension components include springs and a shock absorbers and join a vehicle wheel to a vehicle body while permitting the wheel to move in relation to the vehicle body in a controlled fashion in conjunction with other suspension components including a lower control arm and steering links.

### BRIEF DESCRIPTION OF THE DRAWINGS

FIG. 1 is a diagram of an example vehicle suspension.

FIG. 2 is a diagram of an example graph of kinematic curves.

FIG. 3 is a flowchart diagram of an example process to determine vehicle suspension design.

FIG. 4 is a flowchart diagram of an example process to manufacture a vehicle based a vehicle suspension design.

### DETAILED DESCRIPTION

Operating characteristics of vehicle suspension components depends upon the suspension architecture, selection of components and the locations at which the components are attached to each other and the vehicle body. The suspension architecture determines the type of suspension components to be used in the suspension design. The suspension components, including MacPherson struts, can be selected based on vehicle weight and required wheel travel, for example. Once the size and travel of vehicle suspension components are selected, the suspension geometry can be determined. Suspension geometry includes the arrangement of suspension components and the location of hard-points, which are locations at which suspension components are attached to the vehicle's body. For a given set of vehicle suspension components, suspension geometry will determine the kinematic characteristics of the vehicle suspension. Kinematic characteristics include wheel attitude and suspension travel.

In the early stages of vehicle suspension design and development, decisions are generally made regarding suspension architecture within the constraints of a given packaging space, vehicle weight and required travel. Kinematic characteristics are traditionally derived from a disciplined model, where a disciplined model is a software program that studies the behavior of interconnected rigid and flexible mechanical components as they undergo translational and rotational displacements as a result of applied forces or motion as measured by displacement, velocity and acceleration. Disciplined modeling includes multi-body dynamic modeling/simulation of an entire suspension system subjected to spindle input forces or motion. Disciplined modeling be performed by commercially available multi-body dynamic (MBD) software, examples of which include the ADAMS software package provided by MSC Software Corporation of Santa Ana, Calif., and Virtual Lab Motion software package provided by LMS International (a subsidiary of Siemens AG) of Leuven, Belgium.

Disclosed herein is method including simulating behavior of a vehicle suspension component based on sampling a geometry space including vehicle suspension component hard-points using Gaussian process modeling and determining one or more vehicle suspension component geometries including the vehicle suspension component hard-points based on first kinematic curves corresponding to behavior of the vehicle suspension component. The vehicle suspension component hard-points can include locations at which the vehicle suspension component attaches to a vehicle body. The vehicle suspension component can include a MacPherson strut including a lower control arm that attaches a vehicle wheel to the vehicle. Manufacturing the vehicle can include configuring the vehicle suspension component to determined vehicle suspension parameters including attaching the vehicle at the vehicle suspension components at determined hard-points to permit a vehicle wheel to move relative to the vehicle including steering the vehicle wheel. Vehicle suspension parameters can include bushing stiffness, geometry control points and material properties. The first kinematic curves can include curves describing vehicle wheel attitude and vehicle suspension travel. Sampling the geometry space can include sampling vehicle suspension component hard-points based on Bayesian optimization to minimize errors determined by comparing second kinematic curves iteratively generated by modeling software to the first kinematic curves.

Bayesian optimization can include Gaussian process modeling. Comparing the second kinematic curves to the first kinematic curves can be based on curvature, slope, minimum value, maximum value, and value at one specific wheel travel including zero wheel travel, maximum wheel travel, and minimum wheel travel. Gaussian process modeling can determine a best geometry by determining a minimum error between first kinematic curves and second kinematic curves. Gaussian process modeling can determine one or more other geometries that are similar to the best geometry based on determining errors between first kinematic curves and second kinematic curves similar to the minimum error. The Gaussian process modeling can end when the minimum error is less than a user defined threshold or software modeling determines an unfeasible design. Gaussian process modeling can being by one or more of beginning by randomly sampling the geometry space and beginning with a previously determined geometry. Vehicle hard points can include a drive shaft, front and rear lower control arm, tie rod, and MacPherson strut.

Further disclosed is a computer readable medium, storing program instructions for executing some or all of the above method steps. Further disclosed is a computer programmed for executing some or all of the above method steps, including a computer apparatus, programmed to simulate behavior of a vehicle suspension component based on sampling a geometry space including vehicle suspension component hard-points using Gaussian process modeling and determine one or more vehicle suspension component geometries including the vehicle suspension component hard-points based on first kinematic curves corresponding to behavior of the vehicle suspension component. The vehicle suspension component hard-points can include locations at which the vehicle suspension component attaches to a vehicle body. The vehicle suspension component can include a MacPherson strut including a lower control arm that attaches a vehicle wheel to the vehicle. Manufacturing the vehicle can include configuring the vehicle suspension component to determined vehicle suspension parameters including attaching the vehicle at the vehicle suspension components at determined hard-points to permit a vehicle wheel to move relative to the vehicle including steering the vehicle wheel. Vehicle suspension parameters can include bushing stiffness, geometry control points and material properties. The first kinematic curves can include curves describing vehicle wheel attitude and vehicle suspension travel. Sampling the geometry space can include sampling vehicle suspension component hard-points based on Bayesian optimization to minimize errors determined by comparing second kinematic curves iteratively generated by modeling software to the first kinematic curves.

The computer can be further programmed to include Bayesian optimization as a part of Gaussian process modeling. Comparing the second kinematic curves to the first kinematic curves can be based on curvature, slope, minimum value, maximum value, and value at one specific wheel travel including zero wheel travel, maximum wheel travel, and minimum wheel travel. Gaussian process modeling can determine a best geometry by determining a minimum error between first kinematic curves and second kinematic curves. Gaussian process modeling can determine one or more other geometries that are similar to the best geometry based on determining errors between first kinematic curves and second kinematic curves similar to the minimum error. The Gaussian process modeling can end when the minimum error is less than a user defined threshold or software modeling determines an unfeasible design. Gaussian process modeling can being by one or more of beginning by randomly sampling the geometry space and beginning with a previously determined geometry. Vehicle hard points can include a drive shaft, front and rear lower control arm, tie rod, and MacPherson strut.

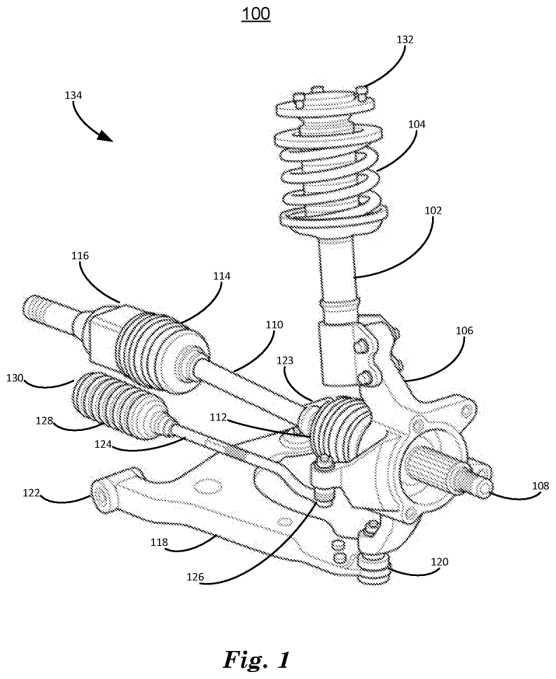

FIG. 1 is a diagram of example suspension components 100 including a MacPherson strut 102. MacPherson strut 102 includes a spring 104 and is attached to a wheel hub 106 and the vehicle body at hard-point 132. Wheel hub 106 includes a wheel spindle 108 that supports attachment of a vehicle wheel. Wheel spindle 108 can either be fixed to the wheel hub 106 or moveably attached to permit the wheel spindle 108 to be rotationally driven by drive shaft 110. Drive shaft 110 is connected to the wheel spindle 108 with a first flexible coupling 112 and connected to the vehicle body at hard-point 116 with a second flexible coupling 114 that permits the drive shaft 110 to rotationally drive the wheel spindle 108 while the wheel spindle 108 moves along with the wheel hub 106 in response to spindle input loads applied by the vehicle wheel responding to changes in a roadway surface, i.e. bumps.

Motion of the wheel hub 106 in response to vehicle wheel motion is constrained by the MacPherson strut 102, which changes length in response to wheel hub 106 motion and lower control arm 118, which is movably attached to the wheel hub 106 by ball joint 120 and to the vehicle body at hard-point 122 and 123. The wheel hub 106 can be steered by being rotated on an axis formed by ball joint 120 and rotation of the MacPherson strut 102 by motion of steering tie rod 124. Steering tie rod 124 is moveably connected to the wheel hub 106 by tie rod end 126 and is connected to a steering assembly rigidly connected to the vehicle body at hard-point 130 by a tie rod flexible coupling 128 that permits the tie rod 124 to rotate (steer) the wheel hub 106 while the wheel hub 106 moves up and down in response to vehicle wheel motion.

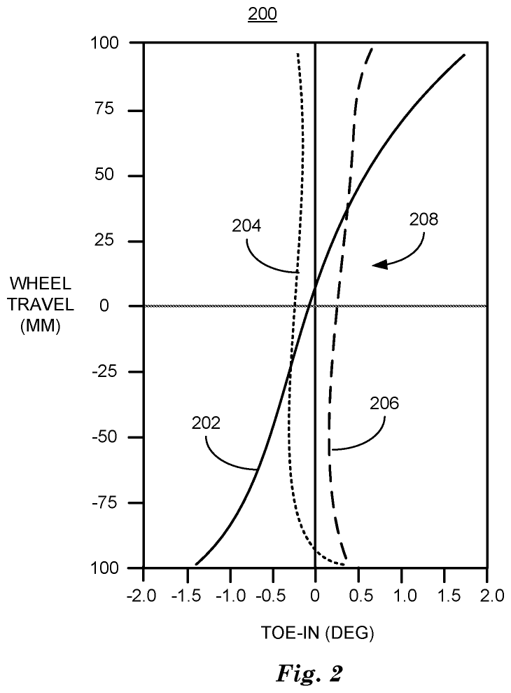

Hard-points 116, 122, 123, 130, 132 (collectively hard-points 134) are locations at which moveable portions of suspension components 100 attach to non-moveable portions of a vehicle body. The positioning of hard-points 134 determines the kinematic characteristics of the vehicle. This positioning of hard-points 134 is normally exercised by an engineer, using an off-the-shelf multi-body dynamics modelling and simulation tool (such as ADAMS) to determine the kinematic performance of the particular design. The kinematics, essentially the relationship between wheel attitude and suspension travel are obtained in terms of curves illustrated in FIG. 2.

FIG. 2 is a diagram of an example graph 200 of kinematic curves 208 (collectively kinematic curves 208). Graph 200 plots vehicle wheel attitude and vehicle wheel travel, with wheel toe-in in degrees on the x-axis vs. wheel travel in millimeters on the y-axis. Wheel toe-in is an angular measure of the degree to which a vehicle wheel turns towards a center line of the vehicle, while wheel travel measures the vertical displacement of a vehicle wheel with respect to the vehicle body as the wheel moves up and down. Kinematic curves 208 correspond to compound wheel movement (both toe-in and travel) corresponding to three different arrangements of hard-points. Each kinematic curve 208 corresponds to motion of a different point on the suspension in response to a driving force, i.e. wheel motion caused by a roadway, for example. Each kinematic curve 208 typically would result in a vehicle suspension design that would be perceived by a passenger as having different ride and handling characteristics.

Kinematic curves 208 can be evaluated to determine kinematic requirements related to the performance of the design. This can be evaluated by taking statistical and/or geometric characteristics from these curves. For example, the slope of the curve as it crosses the x-axis is a characteristic of a curve that corresponds to a kinematic requirement. The minimum or maximum x-value achieved by a curve over a given wheel travel range on the x-axis, in this example +/−100 mm can correspond to a kinematic requirement, for example. These kinematic requirements correspond to the kinematic effects of a set of design parameters, where kinematic effects correspond to the characteristics that a user would experience as vehicle “ride”, defined as how the vehicle suspension would be perceived by a user as the vehicle travels over a roadway.

Based on kinematic requirements corresponding to desirable ride and handling characteristics a kinematic curve 208 can be selected that corresponds to the desirable characteristics. Sets of suspension hard-points 134 can be input to simulation and modeling software as discussed above in relation to FIG. 1 to determine the kinematic curves 208 corresponding to the hard-points 116, 122, 123, 130, 132. It is known to compare the output kinematic curves 208 corresponding to a particular set of hard-points to kinematic curves 208 having desired kinematic characteristics and modify the locations of hard-points 134 in an attempt to make the next iteration of simulation produce kinematic curves 208 that more closely match the kinematic curves 208 with desirable characteristics. This design process can be time intensive as an engineer has to input a particular set of hard-points, pass it through the simulation tool (which can take several minutes to process), and observe the kinematic curves, and then repeat the whole process to refine the design. Thus, generating one design that meets the desired kinematic constraints can in prior techniques take multiple weeks and consume significant computing resources.

Techniques discussed herein improve the suspension design process by applying artificial intelligence techniques to the design process to reduce time-intensive aspects of the design process. Techniques discussed herein can input a set of hard-point locations and corresponding kinematic curves and learn the relationship between the hard-point locations and kinematic curves using Gaussian Process Modelling (GPM). GPM is a technique for learning input-output mappings for a MacPherson strut suspension design process based on limited training data. In this example, GPM is used to predict a set of kinematic curves corresponding to hard-points for MacPherson strut suspension. Predicting the kinematic curves corresponding to hard-points can reduce the amount of time required to select hard-points for a MacPherson struct suspension design process from multiple weeks to less than one day, for example.

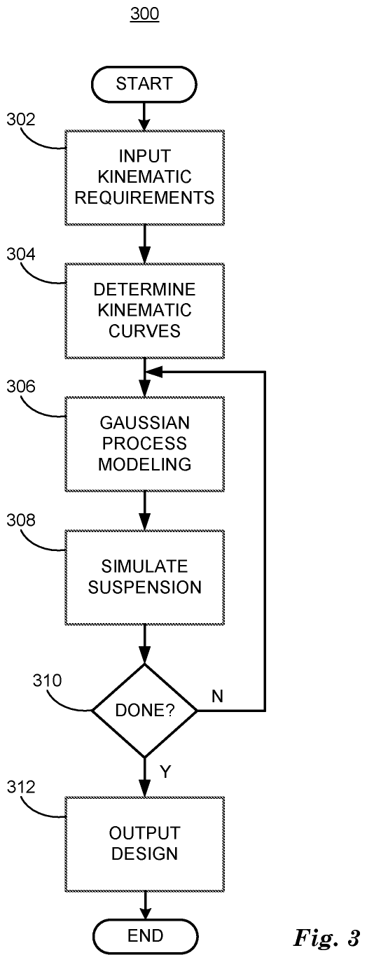

FIG. 3 is a block diagram of a process 300 for determining MacPherson strut suspension design based on Gaussian process modeling. Process 300 can be implemented by a processor of computing device, taking as input information from sensors, and executing commands, and outputting object information, for example. Process 300 includes multiple blocks that can be executed in the illustrated order. Process 300 could alternatively or additionally include fewer blocks or can include the blocks executed in different orders.

Process 300 begins at block 302 where MacPherson strut suspension design process 300 inputs kinematic requirements. Kinematic requirements can be expressed as statistical characteristics of kinematic curves 208, for example, as discussed above in relation to FIG. 2. Kinematic requirements. Kinematic requirements input at block 302 can be selected by a user to produce output hard-points 134 that satisfy user requirements for suspension design. For example, the kinematic requirements can be selected to produce a smooth riding vehicle ride or a vehicle with high cornering performance, among other characteristics.

At block 304 the input kinematic requirements are transformed into kinematic curves 208 in a reverse of the process described in relation to FIG. 2. In this example kinematic requirements are converted into kinematic curves 208 by determining kinematic curves 208 that correspond to the statistical characteristics included in the kinematic requirements. For example, kinematic requirements regarding the slope of a curve and minimum and maximum values can be combined with a kinematic requirement regarding the maximum curvature corresponding to maximum permitted values for a first derivative of the curve to determine desired kinematic curves 208. The kinematic requirements can be based on a previously determined geometry from a previous design as a starting point, for example.

At block 306 the kinematic curves are input to a Gaussian process model (GPM) that iteratively interacts with simulation and modeling software at block 308 to determine a set of hard-points 134 which will produce a set of kinematic curves 208 that correspond to desired kinematic curves input from block 304. GPM is a mathematical process that infers a statistical relationship between kinematic curves 208 output from a complex process like simulation and modeling software and input hard-points 134. GPM applies Bayesian optimization to a complex, multivariate problem like modeling and simulation to predict ranges of outputs based on ranges of inputs. Bayesian optimization is a statistical process that determines a posterior or output probability based on prior or previously measured probabilities. Bayesian inference is defined by equation (1):

$$P ( A \vert B ) = \frac{P ( B \vert A ) P ( A )}{P ( B )} \qquad ( 1 )$$

This is read as “the probability of A conditioned on the probability of B is equal to the probability of B conditioned on the probability of A times the probability of A divided by the probability of B,” where conditioned refers to probabilities that assume the probabilities of the following variable. A Gaussian process model is an extension of Gaussian probability distribution theory that applies Gaussian statistics to functions. In this example the output kinematic curves 208 are variable A and the input hard-points 134 are variable B. Gaussian process modeling assumes that differences between optimum kinematic curves 208 and previously unknown kinematic curves corresponding to kinematic curves 208 output from simulation and modeling software at block 308 have determined Gaussian probability distributions with respect to the distributions of locations of input hard-points 134. What this means is that a desired change in output kinematic curves 208 can be predicted based on changes in locations of input hard-points 134. The relationship between output kinematic curves 208 and input hard-points 134 is different for each arrangement of suspension components and is determined by Gaussian process modeling by iteratively executing simulation and modeling software using a plurality of sets of hard-points 134 that vary systematically. By varying the input sets of hard-points systematically, Gaussian process modeling can determine the Bayesian statistics that determine which set of hard-points 134 produce desired kinematic curve 208 that correspond to desired kinematic requirements.

GPM applies Bayesian optimization to simulation and modeling software by determining covariance functions between Gaussian probability distributions corresponding to functions that map multiple inputs to multiple outputs. For example, the output kinematic curves for a set of input hard-points 134 depend upon the location of each hard-point 134 in three-dimensional (3D) space. The effect on output kinematic curves based on changing the 3D location of a single hard-point 134 will differ depending upon changes in locations of the other hard-points 134 occurring at the same time. Covariance functions measure the probability distribution of changes in output kinematic curves based on changes in each of the 3D locations of hard-points 134. GPM models the relationship between input hard-points 134 and output kinematic curves as Gaussian distributions and can be used to efficiently sample the space of possible input hard-points 134 to produce output kinematic curves that most closely match the input kinematic curves. Error terms formed by measuring a distance between kinematic curves output by modeling and simulation 308 process and input kinematic curves can be used to determine 3D locations of input hard-points 134 for further iterations of modeling and simulation 308 software.

At block 310 process 300 determines whether the kinematic curves 208 output by simulation and modeling software at block 308 are within a threshold of desired kinematic curves 208 determined at block 304 to indicate that process 300 is done. In one example, if the error term formed by measuring a sum of Euclidian distances between the output kinematic curves 208 and the desired kinematic curves 208 are greater than a user input threshold, process 300 returns to block 306 where GPM determines a new set of hard-points 134 to input to simulation and modeling software at block 308 to produce a new set of output kinematic curves. GPM can also reach a stopping point when the algorithm detects an unfeasible design, i.e. when the modeling software cannot produce a usable result. When the errors between kinematic curves 208 output by modeling and simulation at block 308 and desired kinematic curves 208 is less than a user input threshold, process 300 passes to block 312.

At block 312 the 3D locations of hard-points 134 that produce kinematic curves 208 output by mapping and simulation software have been determined to match desired kinematic curves 208 and therefore correspond to suspension geometry that provides the desired input kinematic requirements are output. Following block 312 process 300 ends.

GPM processing improves the MacPherson strut suspension design process by outputting one or more design solutions including one or more sets of hard-points 134 that match kinematic requirements without requiring a design engineer to repeatedly modify hard-point 134 3D locations, input the hard-point 134 3D locations to modeling and simulation 308 software and then manually analyze kinematic curves to determine whether or not the design meets the determined kinematic requirements. GPM processing can yield one or more design solutions that correspond to good design solutions, i.e. that match the input kinematic curves to varying degrees and are therefore similar to a best geometry having a minimum error. For example, output design solutions might produce output kinematic curves 208 that do not match the desired kinematic curves 208 exactly, because each set of output kinematic curves 208 will include a non-zero error term, but all of the output design solutions will produce kinematic curves 208 that approximately match the desired kinematic curves 208, where the error between the output design solutions and the input kinematic curves 208 will be less than or equal to the user input threshold.

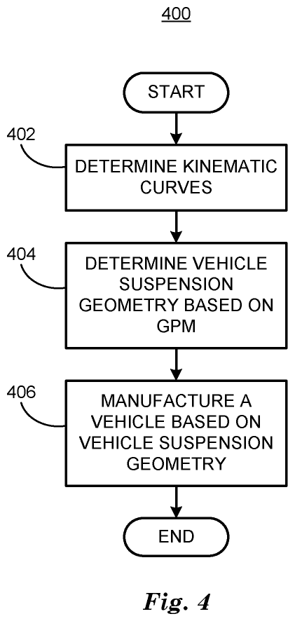

FIG. 4 is a diagram of a flowchart, described in relation to FIGS. 1-3, of a process 400 for manufacturing a vehicle based on determining MacPherson strut suspension geometry using GPM. Process 400 can be implemented by a processor of computing device, taking as input information from sensors, and executing commands, and outputting object information, for example. Process 400 includes multiple blocks that can be executed in the illustrated order. Process 400 could alternatively or additionally include fewer blocks or can include the blocks executed in different orders.

Process 400 begins at a block 402, where a computing device determines kinematic curves 208 based on kinematic requirements as discussed above in relation to FIG. 3. The kinematic requirements can be determined by randomly sampling the space of possible MacPherson strut suspension geometries or starting with a previous design for MacPherson strut suspension geometries.

At a block 404 the computing device uses GPM processing to determine a plurality of MacPherson strut suspension geometries based on 3D locations of hard-points 134 corresponding to MacPherson strut suspension geometries. The 3D locations of hard-points 134 are input to modeling and simulation 308 software which calculates kinematic curves corresponding to the hard-points 134. GPM process determines 3D locations of hard-points 134 based on reducing uncertainty and predicting how well the resulting kinematic curves output from the modeling and simulation software will match kinematic curves 202, 204, 206. When GPM processing has determined one or more sets of 3D locations for hard-points 134, the 3D locations of hard-points 134 are output as design solutions.

At block 406 a set of 3D locations of hard-points 134 output as a design solution for MacPherson strut suspension geometry and can be used to manufacture a vehicle. The resulting vehicle will have ride characteristics corresponding to the kinematic requirements input to the MacPherson strut suspension design process 300. Following block 406 process 400 ends.

Computing devices such as those discussed herein generally each include commands executable by one or more computing devices such as those identified above, and for carrying out blocks or steps of processes described above. For example, process blocks discussed above may be embodied as computer-executable commands.

Computer-executable commands may be compiled or interpreted from computer programs created using a variety of programming languages and/or technologies, including, without limitation, and either alone or in combination, Java™, C, C++, Python, Julia, SCALA, Visual Basic, Java Script, Perl, HTML, etc. In general, a processor (e.g., a microprocessor) receives commands, e.g., from a memory, a computer-readable medium, etc., and executes these commands, thereby performing one or more processes, including one or more of the processes described herein. Such commands and other data may be stored in files and transmitted using a variety of computer-readable media. A file in a computing device is generally a collection of data stored on a computer readable medium, such as a storage medium, a random access memory, etc.

A computer-readable medium includes any medium that participates in providing data (e.g., commands), which may be read by a computer. Such a medium may take many forms, including, but not limited to, non-volatile media, volatile media, etc. Non-volatile media include, for example, optical or magnetic disks and other persistent memory. Volatile media include dynamic random access memory (DRAM), which typically constitutes a main memory. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, or any other medium from which a computer can read.

All terms used in the claims are intended to be given their plain and ordinary meanings as understood by those skilled in the art unless an explicit indication to the contrary in made herein. In particular, use of the singular articles such as “a,” “the,” “said,” etc. should be read to recite one or more of the indicated elements unless a claim recites an explicit limitation to the contrary.

The term “exemplary” is used herein in the sense of signifying an example, e.g., a reference to an “exemplary widget” should be read as simply referring to an example of a widget.

The adverb “approximately” modifying a value or result means that a shape, structure, measurement, value, determination, calculation, etc. may deviate from an exactly described geometry, distance, measurement, value, determination, calculation, etc., because of imperfections in materials, machining, manufacturing, sensor measurements, computations, processing time, communications time, etc.

In the drawings, the same reference numbers indicate the same elements. Further, some or all of these elements could be changed. With regard to the media, processes, systems, methods, etc. described herein, it should be understood that, although the steps or blocks of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claimed invention.

1. A computer, comprising a processor; and
a memory, the memory including instructions to be executed by the processor to:
simulate behavior of a vehicle suspension component based on sampling a geometry space including vehicle suspension component hard-points using Gaussian process modeling; and
determine one or more vehicle suspension component geometries including the vehicle suspension component hard-points based on first kinematic curves corresponding to behavior of the vehicle suspension component.

2. The computer of claim 1, wherein the vehicle suspension component hard-points are locations at which the vehicle suspension component attaches to a vehicle body.

3. The computer of claim 1, wherein the vehicle suspension component is a MacPherson strut including a lower control arm that attaches a vehicle wheel to the vehicle.

4. The computer of claim 3, wherein manufacturing the vehicle includes configuring the vehicle suspension component according to determined suspension parameters including attaching the vehicle suspension components at determined hard-points to permit a vehicle wheel to move relative to the vehicle including steering the vehicle wheel.

5. The computer of claim 1, wherein the first kinematic curves include curves describing vehicle wheel attitude and vehicle suspension travel.

6. The computer of claim 1, the instructions further including instructions to sample the geometry space including vehicle suspension component hard-points based on Bayesian optimization to minimize errors determined by comparing second kinematic curves iteratively generated by modeling software to the first kinematic curves.

7. The computer of claim 6, the instructions further including instructions to compare the second kinematic curves to the first kinematic curves based on curvature, slope, minimum value, maximum value, and value at one specific wheel travel including zero wheel travel, maximum wheel travel, and minimum wheel travel.

8. The computer of claim 7, wherein Gaussian process modeling determines a best geometry by determining a minimum error between first kinematic curves and second kinematic curves.

9. The computer of claim 8, wherein Gaussian process modeling determines one or more other geometries that are similar to the best geometry based on determining errors between first kinematic curves and second kinematic curves similar to the minimum error.

10. The computer of claim 1, the instructions further including instructions to begin Gaussian process modeling by one or more of beginning by randomly sampling the geometry space and beginning with a previously determined geometry.

11. A method, comprising:
simulating behavior of a vehicle suspension component based on sampling a geometry space including vehicle suspension component hard-points using Gaussian process modeling; and
determining one or more vehicle suspension component geometries including the vehicle suspension component hard-points based on first kinematic curves corresponding to behavior of the vehicle suspension component.

12. The method of claim 11, wherein the vehicle suspension component hard-points are locations at which the vehicle suspension component attaches to a vehicle body.

13. The method of claim 11, wherein the vehicle suspension component is a MacPherson strut including a lower control arm that attaches a vehicle wheel to the vehicle.

14. The method of claim 13, wherein manufacturing the vehicle includes configuring the vehicle suspension component to determined vehicle suspension parameters including attaching the vehicle at the vehicle suspension components at determined hard-points to permit a vehicle wheel to move relative to the vehicle including steering the vehicle wheel.

15. The method of claim 11, wherein the first kinematic curves include curves describing vehicle wheel attitude and vehicle suspension travel.

16. The method of claim 11, further comprising sampling the geometry space including vehicle suspension component hard-points based on Bayesian optimization to minimize errors determined by comparing second kinematic curves iteratively generated by modeling software to the first kinematic curves.

17. The method of claim 16, further comprising comparing the second kinematic curves to the first kinematic curves based on curvature, slope, minimum value, maximum value, and value at one specific wheel travel including zero wheel travel, maximum wheel travel, and minimum wheel travel

18. The method of claim 17, wherein Gaussian process modeling determines a best geometry by determining a minimum error between first kinematic curves and second kinematic curves.

19. The method of claim 18, wherein Gaussian process modeling determines one or more other geometries that are similar to the best geometry based on determining errors between first kinematic curves and second kinematic curves similar to the minimum error.

20. The method of claim 11, further comprising beginning Gaussian process modeling by one or more of beginning by randomly sampling the geometry space and beginning with a previously determined geometry.
